(19) United States
(12) Patent Application Publication
(10) Pub. No.: US 2018/0156431 A1
(43) Pub. Date: Jun. 7, 2018

(54) ELECTRIC DRIVER AND ILLUMINATION DEVICE

(71) Applicant: OSRAM GmbH, Munich (DE)

(72) Inventors: XiHe Zhuang, Shenzhen (CN); Jianbo Gao, Shenzhen (CN); Wengen Tan, Shenzhen (CN); Yizhi Huang, Shenzhen (CN)

(21) Appl. No.: 15/831,420

(22) Filed: Dec. 5, 2017

(30) Foreign Application Priority Data
Dec. 6, 2016 (CN) 201621329196.X

(51) Int. Cl. F21V 23/00; F21V 29/15; H05K 1/18; H05K 1/02

(52) U.S. Cl. CPC F21V 23/003; F21V 29/15; F21Y 2115/10; H05K 1/0203; H05K 1/18

(57) ABSTRACT

The utility model relates to an electric driver and an illumination device. The electric driver comprises: a carrier; a first electrical component and a second electrical component, wherein the first electrical component and the second electrical component are provided on the carrier; and a heat insulation structure, wherein the second electrical component comprises a first heat insulator surrounding the second electrical component and a second heat insulator surrounding the first heat insulator, wherein a gap is provided between the first heat insulator and a second heat insulator. The electric driver according to the present utility model improves the lifetime of capacitors, is low-cost, and has a compact structure.

### CROSS-REFERENCE TO RELATED APPLICATION

This application claims priority to Chinese Patent Application Serial No. 201621329196.X, which was filed Dec. 6, 2016, and is incorporated herein by reference in its entirety.

### TECHNICAL FIELD

The present utility model relates to an electric driver and an illumination device.

Since LED light sources have high illumination efficiency, the LED illumination technique is tremendously used in illumination devices. A driver of an LED illumination device are generally provided with a variety of electrical components, comprising a capacitor, an electrolytic capacitor (E-cap) and a metallized polypropylene film capacitor (MKP cap) in particular, and other components. Those components are enveloped by an potting material so as to improve the thermal conductivity and airtightness of a high power LED driver. For example, as shown in FIG. 1, a schematic diagram of an electric driver according to the prior art is shown in FIG. 1, wherein the arrows show the directions of heat conducted between electrical components. The electric driver comprises a variety of electrical components provided on a circuit board. According to the design in FIG. 1, heat generated by power components (for example, a transformer, MOSFET, and a rectifier) can be easily conducted and the heat is dissipated.

However, since other electrical components of the electric driver are all assembled in the proximity of capacitors, heat from other electrical components, for example, the heat from MOSFET and the transformer, will be easily conducted to the capacitors, and the temperature of the capacitors having less heat will become higher due to the heat conducted from other electrical components. The lifetime of capacitors is quite easily influenced by the temperature, and moreover, the lifetime of capacitors will be reduced by 50% with the temperature increased by 10° C. each time. After the potting material is used, the heat will be easily and rapidly conducted to the capacitors, which further quickens the damage on the capacitors. In the prior art, in order to prolong the lifetime of capacitors, capacitors having a long lifetime and a high rated temperature are used on the one hand, whereas such capacitors are costly; plastic housings are used for wrapping the capacitors one the other hand, whereas the plastic housings are costly. Moreover, in order to fix the plastic housings on the circuit board, the circuit board must be provided with special mounting holes, which not only occupies space, and increases the product volume, but also increases difficulties in product design.

### BACKGROUND

Since LED light sources have high illumination efficiency, the LED illumination technique is tremendously used in illumination devices. A driver of an LED illumination device are generally provided with a variety of electrical components, comprising a capacitor, an electrolytic capacitor (E-cap) and a metallized polypropylene film capacitor (MKP cap) in particular, and other components. Those components are enveloped by an potting material so as to improve the thermal conductivity and airtightness of a high power LED driver. For example, as shown in FIG. 1, a schematic diagram of an electric driver according to the prior art is shown in FIG. 1, wherein the arrows show the directions of heat conducted between electrical components. The electric driver comprises a variety of electrical components provided on a circuit board. According to the design in FIG. 1, heat generated by power components (for example, a transformer, MOSFET, and a rectifier) can be easily conducted and the heat is dissipated.

However, since other electrical components of the electric driver are all assembled in the proximity of capacitors, heat from other electrical components, for example, the heat from MOSFET and the transformer, will be easily conducted to the capacitors, and the temperature of the capacitors having less heat will become higher due to the heat conducted from other electrical components. The lifetime of capacitors is quite easily influenced by the temperature, and moreover, the lifetime of capacitors will be reduced by 50% with the temperature increased by 10° C. each time. After the potting material is used, the heat will be easily and rapidly conducted to the capacitors, which further quickens the damage on the capacitors. In the prior art, in order to prolong the lifetime of capacitors, capacitors having a long lifetime and a high rated temperature are used on the one hand, whereas such capacitors are costly; plastic housings are used for wrapping the capacitors one the other hand, whereas the plastic housings are costly. Moreover, in order to fix the plastic housings on the circuit board, the circuit board must be provided with special mounting holes, which not only occupies space, and increases the product volume, but also increases difficulties in product design.

### SUMMARY

In order to solve the above-mentioned technical problem, the present utility model provides a new electric driver and an illumination device. The electric driver and the illumination device according to the present utility model can effectively decrease the temperature of capacitors, thereby improving the lifetime of the capacitors, and moreover, they have low costs, and can be easily assembled and have compact structures.

The object of the present utility model is realized by means of such an electric driver, i.e., an electric driver comprising: a carrier; a first electrical component and a second electrical component, wherein the first electrical component and the second electrical component are provided on the carrier; and a heat insulation structure, wherein the second electrical component is separated from the first electrical component by means of the heat insulation structure, wherein the heat insulation structure comprises a first heat insulator surrounding the second electrical component and a second heat insulator surrounding the first heat insulator, wherein a gap is provided between the first heat insulator and a second heat insulator.

According to the electric driver of the present utility model, a gap is intentionally provided between a plurality of electrical components by means of the heat insulation structure, particularly, for example, between a low-temperature capacitor and a high-temperature high-power component. A gap can advantageously reduce or prevent heat conducted from the high-temperature high-power component to the low-temperature capacitor, and avoid the capacitor from becoming hotter due to the conducted heat. The heat insulation structure has a simple and compact structure, and features low costs and convenient assembly, wherein the first heat insulator can directly mounted and fixed onto the second electrical component, and the second heat insulator can be further provided in the periphery of the first heat insulator.

According to a preferable embodiment in the present utility model, the first electrical component is enveloped by the first medium, the second electrical component is separated from the first medium by means of a gap, and moreover, the second medium is provided in the gap, wherein the second medium has a thermal resistance greater than that of the first medium. The thermal conductivity and airtightness of the first electrical component are improved by enveloping the first electrical component by means of the first medium. However, the gap provided can advantageously reduce or prevent heat being directly conducted from the high-temperature first electrical component to the second electrical component by means of the heat conducted first medium, and thus avoids the second electrical component from increasing temperatures due to the conducted heat, and improves the lifetime of the second electrical component.

According to a preferable embodiment in the present utility model, the electric driver further comprises a housing, wherein the carrier, the first electrical component, and the second electrical component are provided in the housing. The first electrical component and the carrier are encapsulated by filling the first medium in the housing, and the heat from electrical components can be conducted to the housing by means of the heat conducted potting material, and hereby dissipating the heat.

According to a preferable embodiment in the present utility model, the first electrical component is connected to the housing by means of the first medium, and the second electrical component is connected to the housing by means of the second medium. The heat from the first electrical component is directly conducted to the housing by means of the first medium, and the heat therefrom is thereby dissipated by means of the housing; on the other hand, the heat from the second electrical component is directly conducted to the housing by means of the second medium, and the heat therefrom is thereby dissipated by means of the housing.

According to a preferable embodiment in the present utility model, the electric driver further comprises a thermal pad, wherein the end of the second electrical component facing away from the carrier is thermally connected to the housing by means of the thermal pad. For example, the first medium of the potting material is not provided on the top of a capacitor, whereas a thermal pad is provided between the top of the capacitor and the housing, which results in a low temperature of the housing, and reduces the temperature of the capacitor.

According to a preferable embodiment in the present utility model, the first medium is potting material, and the second medium is air. The first medium enhances the air-tightness and thermal conductivity of the first electrical component, and the second medium has a heat resistance greater than that of the first medium, which particularly reduces or prevents the heat from the first electrical component from being conducted to the second electrical component.

According to a preferable embodiment in the present utility model, the first electrical component has higher rated temperature than that of the second electrical component. The first electrical component is generally a high power electrical component with high rated temperature, such as MOSFET, a transformer, and a rectifier.

According to a preferable embodiment in the present utility model, the first heat insulator and the second heat insulator are made of polyethylene terephthalate or fish paper. Materials such as fish paper are used to avoid high costs incurred from needs of using a special mold for manufacturing a plastic housing. Materials such as fish paper require no mold since fish paper is cheap, and is also a commonly used material.

According to a preferable embodiment in the present utility model, the second electrical component is a capacitor. Advantageously, the capacitor is an electrolytic capacitor, and the capacitor has a rated operating temperature lower than that of high-power components. Another object of the present utility model is realized by means of such an illumination device, i.e., an illumination device comprising the electric driver as described in the preceding text. The illumination device according to the present utility model has an electric driver which operates more stably and reliably. Moreover, due to the low cost of the electric driver, the cost for manufacturing the illumination device is thereby reduced.

### BRIEF DESCRIPTION OF THE DRAWINGS

The drawings constitute a portion of the description for further understanding of the present disclosure. These drawings illustrate the embodiments of the present disclosure and explain the principle of the present disclosure together with the description. In the drawings, the same part is represented by the same reference sign. In the drawings,

FIG. 1 shows a schematic diagram of the electric driver according to the prior art;

FIG. 2 shows a schematic diagram of the electric driver according to example 1 of the present utility model;

FIG. 3 shows a schematic diagram of the electric driver according to example 2 of the present utility model; and

FIG. 4 shows a schematic diagram of the electric driver according to example 3 of the present utility model.

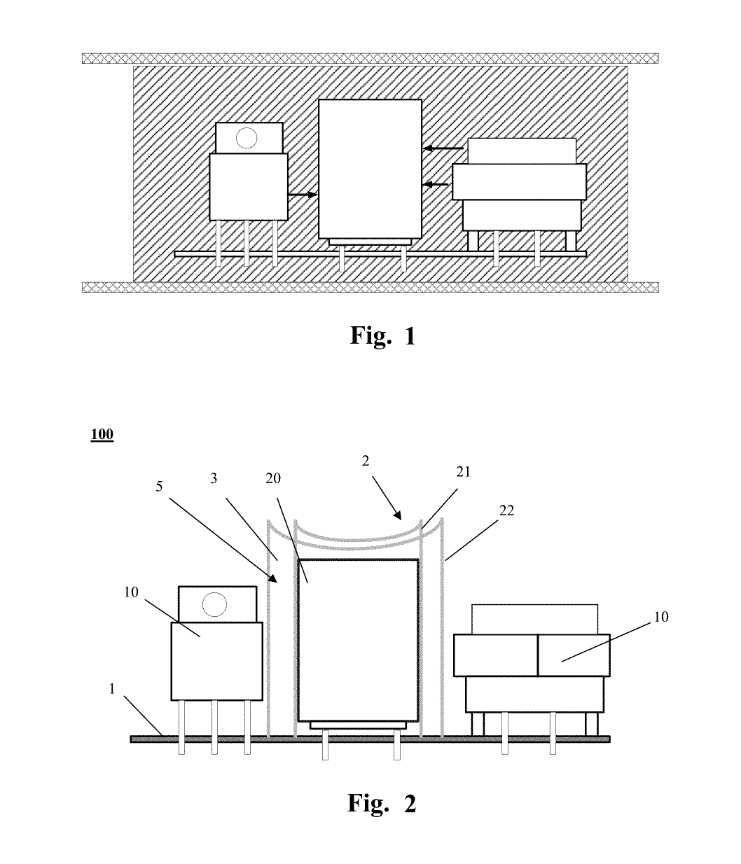

### DETAILED DESCRIPTION

FIG. 2 shows a schematic diagram of the electric driver 100 according to example 1 of the present utility model. The electric driver 100 comprises: a first electrical component 10 and a second electrical component 20, a carrier 1 for bearing the first electrical component 10 and the second electrical component 20, and a heat insulation structure 2; wherein the second electrical component 20 is separated from the first electrical component 10 by means of the heat insulation structure 2, wherein the heat insulation structure 2 comprises a first heat insulator 21 surrounding the second electrical component 20 and a second heat insulator 22 surrounding the first heat insulator 21, wherein a gap 3 is provided between the first heat insulator 21 and a second heat insulator 22.

Advantageously, the first electrical component 10 can be designed to be an electrical component having a high rated temperature and power, such as MOSFET, a transformer, and a rectifier. The second electrical component 20 can be designed to be an electrical component having a low rated temperature and power, such as an electrolytic capacitor. The carrier 1 can be a printed circuit board which electrically and mechanically connects the first electrical component 10 with the second electrical component 20.

Advantageously, the heat insulation structure 2 can be made of two layers of insulation sheet with the first layer of insulation sheet directly mounted and fixed on the second electrical component 20 and with the second layer of insulation sheet surrounding the first layer of insulation sheet, and thereby forming, around the second electrical component 20, the gap 3 separated from the first electrical component 10. The insulation sheets can be made of polyethylene terephthalate (PET) or fish paper. Air is provided between the two layers of insulation sheets. When the first electrical component 10 and the second electrical component 20 are assembled on the same carrier 1, the heat of the first electrical component 10 may be conducted to the second electrical component 20. To that end, the second electrical component 20 is separated from the first electrical component 10 by means of the heat insulation structure 2. Accordingly, the heat of the first electrical component 10 will not be directly conducted to the second electrical component 20. Thus, the temperature of the second electrical component 20 will not be increased due to the heat from the first electrical component 10, which particularly improves the lifetime of the second electrical component 20.

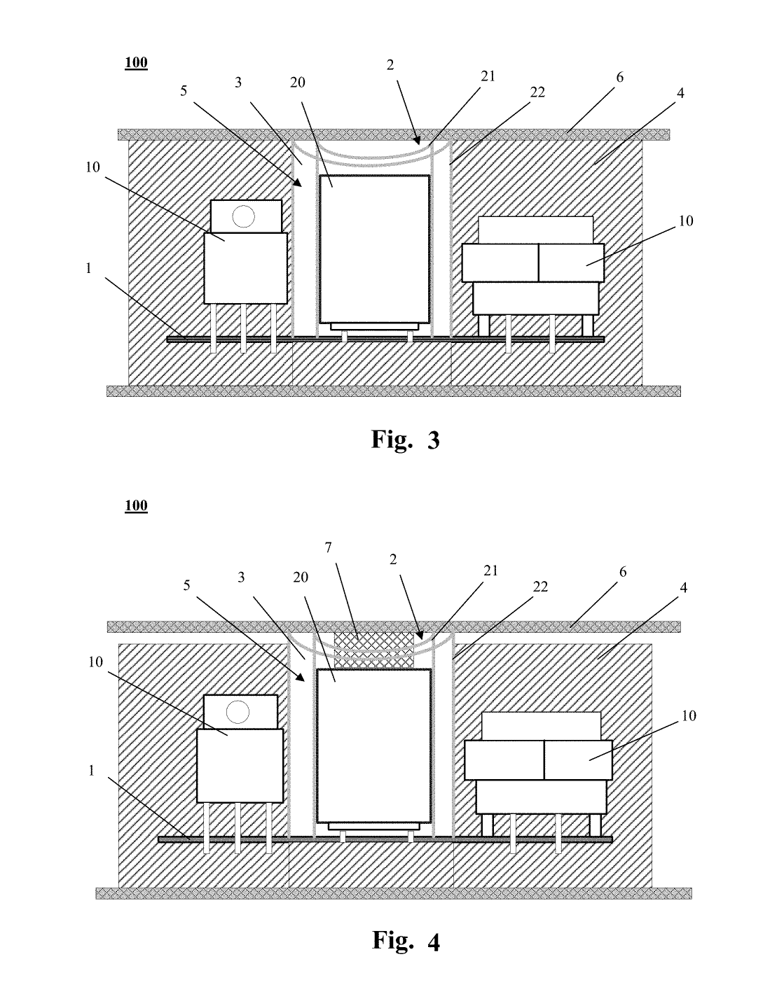

FIG. 3 shows a schematic diagram of the electric driver 100 according to example 2 of the present utility model. The electric driver 100 comprises: a first electrical component 10 and the second electrical component 20, a carrier 1 for bearing the electrical component 10 and the second electrical component 20, and a heat insulation structure 2; the above-mentioned components have structures and functions the same that disclosed in example 1. In addition, the electric driver 100 further comprises a housing 6 for holding the first electrical component 10, the second electrical component 20, and the carrier 1. The housing 6 can be filled with an potting material serving as a first medium 4 and made of, for example, silicon resin or asphalt, and such an potting material is used for sealing at least the first electrical component 10 such that the electrical component is waterproof and dustproof, which ensures that the electrical component is not influenced by the environment outside the housing 6. A second medium 5 having a heat resistance greater than that of the first medium 4, for example, air, is provided between two layers of insulation sheet as a heat insulation structure 2. The second electrical component 20, by means of the heat insulation structure 2, is separated from the first electrical component 10 and the first medium 4 enveloping the first electrical component 10. Accordingly, the heat of the first electrical component 10 will not be directly conducted to the second electrical component 20 or directly conducted to the second electrical component 20 by means of a heat conducted potting material.

In example 2, as shown in FIG. 3, for example, in a vertical direction of the carrier 1, the potting material is filled between the first electrical component 10 and the housing 6. Accordingly, the heat of the first electrical component 10 can be directly conducted to the housing 6 by means of the potting material, and heat is further dissipated by means of the housing 6. Thus, the heat conduction and dissipation performance of the first electrical component is thereby improved. Upon comparison, no potting material is filled between one end of the second electrical component 20 deviating from the carrier 1 and the housing 6, which causes that the heat of the second electrical component 20 substantially is not conducted by means of the potting material, but conducted to the housing 6 by means of air in the gap 3. Therefore, the heat conducted by the second electrical component 20 to the housing is reduced, the temperature of the housing is further reduced, and the stability of the whole driver is guaranteed.

FIG. 4 shows a schematic diagram of the electric driver according to example 3 of the present utility model. Example 3 differs from example 2 in that in a vertical direction of the carrier 1, no potting material is filled between the first electrical component 10 and the housing 6, which advantageously reduces the heat conducted from the first electrical component 10 to the housing 6, thereby reducing the temperature of the housing 6 when the airtightness of the first electrical component 10 is ensured simultaneously.

A thermal pad 7, for example, heat conductive silicone, is further provided between the second electrical component 20 and the housing 6. The thermal pad 7 is particularly provided at one end or top of the second electrical component 20 deviating from the carrier 1, and accordingly, the heat from the second electrical component 20 can be conducted to the housing 6 by means of the thermal pad 7 and the heat is dissipated by means of the housing 6, which further reduces the temperature of the second electrical component 20. In addition, the embodiment of the thermal pad 7 in example 3 as shown in FIG. 4 can be similarly applied to example 2 as shown in FIG. 3 so as to realize highly efficient heat dissipation and rapid temperature reduction of the second electrical component 20, and prolong the lifetime thereof.

The above-mentioned contents are merely preferable embodiments of the present utility model, not used for limiting the present utility model. As for a person skilled in the art, various amendments and changes can be made to the present utility model. Any amendments, equivalent replacements, improvements, and among others made under the spirit and principle of the present utility model shall be included within the scope of protection of the present utility model.

### LIST OF REFERENCE SIGNS

1 carrier
2 heat insulation structure
3 gap
4 first medium
5 second medium
6 housing
7 thermal pad
10 first electrical component
20 second electrical component
21 first heat insulator
22 second heat insulator
100 electric driver

1. An electric driver, comprising:
a carrier;
a first electrical component and a second electrical component, wherein the first electrical component and the second electrical component are provided on the carrier; and
a heat insulation structure, wherein the second electrical component is separated from the first electrical component by means of the heat insulation structure, wherein the heat insulation structure comprises a first heat insulator surrounding the second electrical component and a second heat insulator surrounding the first heat insulator, wherein a gap is provided between the first heat insulator and a second heat insulator.

2. The electric driver according to claim 1, wherein the first electrical component is enveloped by a first medium, the second electrical component is separated from the first medium by means of the gap, and moreover, a second medium is provided in the gap, wherein the second medium has a thermal resistance greater than that of the first medium.

3. The electric driver according to claim 2, wherein the electric driver further comprises a housing, wherein the carrier, the first electrical component and the second electrical component are provided in the housing.

4. The electric driver according to claim 3, wherein the first electrical component is connected to the housing by means of the first medium, and the second electrical component is connected to the housing by means of the second medium.

5. The electric driver according to claim 3, wherein the electric driver further comprises a thermal pad, wherein the end of the second electrical component facing away from the carrier is thermally connected to the housing by means of the thermal pad.

6. The electric driver according to claim 2, wherein the first medium is potting material and the second medium is air.

7. The electric driver according to claim 1, wherein the first electrical component has higher rated temperature than that of the second electrical component.

8. The electric driver according to claim 1, wherein the first heat insulator and the second heat insulator are made of polyethylene terephthalate or fish paper.

9. The electric driver according to claim 1, wherein the second electrical component is a capacitor.

10. An illumination device, comprising:
a electric driver, wherein the electric driver comprises:
a carrier;
a first electrical component and a second electrical component, wherein the first electrical component and the second electrical component are provided on the carrier; and
a heat insulation structure, wherein the second electrical component is separated from the first electrical component by means of the heat insulation structure, wherein the heat insulation structure comprises a first heat insulator surrounding the second electrical component and a second heat insulator surrounding the first heat insulator, wherein a gap is provided between the first heat insulator and a second heat insulator.
